(19) United States
(12) Patent Application Publication
(10) Pub. No.: US 2024/0087588 A1
(43) Pub. Date: Mar. 14, 2024

(54) ADAPTIVE GAIN CONTROL WITH LEARNED GAINS AND CALCULATED GAINS BASED ON THE FREQUENCY DOMAIN

(71) Applicant: Lenovo (Singapore) Pte. Ltd., New Tech Park (SG)

(72) Inventors: John W. Nicholson, Cary, NC (US); Daryl C. Cromer, Raleigh, CN (US); Howard Locker, Cary, NC (US)

(21) Appl. No.: 17/932,005

(22) Filed: Sep. 14, 2022

(51) Int. Cl. G10L 21/034; G10L 17/04; G10L 17/22; G10L 25/18; G10L 25/24; G10L 25/78

(52) U.S. Cl. CPC G10L 21/034; G10L 17/04; G10L 17/22; G10L 25/18; G10L 25/24; G10L 25/78

(57) ABSTRACT

Apparatus, methods, and computer program products that include Adaptive Gain Control with learned gains and calculated gains based on the frequency domain are disclosed. One apparatus includes a processor and a memory that stores code executable by the processor to receive an audio signal from an audio input device and implement an Adaptive Gain Control to adjust a gain of the audio signal. The gain can include a learned gain and/or a calculated gain based on the frequency domain. Methods and computer program products that include and/or perform the operations and/or functions of the apparatus are also disclosed.

### FIELD

The subject matter disclosed herein relates to Adaptive Gain Control (AGC) and more particularly relates to AGC with learned gains and calculated gains based on the frequency domain.

### DESCRIPTION OF THE RELATED ART

Adaptive Gain Control (AGC) provides a mechanism for systems to adjust the range of sensitivity to the input of a microphone. Computing devices implement and use contemporary AGC to capture and amplify the user's voice to a consistent level. With a laptop computer, for example, the distance from the user to the laptop computer can vary during a video call or recording when the user leans near the laptop computer when looking at the screen, looks away from the laptop while making notes, leans back in their chair, or stands up and/or walks around. Contemporary AGC attempts to provide a constant voice input level that is neither clipped nor too quiet in each of these instances.

However, when the user is quiet and listening, contemporary AGC typically continues to increase the gain in case the user is away from the microphone and is just not being heard. In this case, any noise made (especially near the microphone) is amplified a large amount. Here, while to the individual(s) in the same room as the laptop computer merely hear normal background sounds, others on the call not in the same room as the laptop computer hear loud background sounds.

### BRIEF SUMMARY

Apparatus that can include Adaptive Gain Control (AGC) with learned gains and calculated gains based on the frequency frequency domain are disclosed. One apparatus includes a processor and a memory that stores code executable by the processor. The code is executable by the processor to receive an audio signal from an audio input device and implement an AGC to adjust a gain of the audio signal. In various embodiments, the gain includes a learned gain and/or a calculated gain based on the frequency domain.

Also disclosed are methods that include AGC with learned gains and calculated gains based on the frequency domain. One method includes receiving an audio signal from an audio input device and implementing an AGC to adjust a gain of the audio signal. In various embodiments, the gain includes a learned gain and/or a calculated gain based on the frequency domain.

Computer program products including a computer-readable storage device including code embodied therewith are further disclosed herein. The code is executable by a processor and causes the processor to receive an audio signal from an audio input device and implement an AGC to adjust a gain of the audio signal. In various embodiments, the gain includes a learned gain and/or a calculated gain based on the frequency domain.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIGS. 1A and 1B are schematic block diagrams of various embodiments of a computing device including Adaptive Gain Control (AGC) with learned gains and/or calculated gains based on the frequency domain;

FIG. 2 is a schematic block diagram of one embodiment of a memory device included in the computing devices of FIGS. 1A and 1B;

FIG. 3 is a schematic block diagram of one embodiment of a gain module included in the memory device of FIG. 2;

FIG. 4 is a schematic block diagram of one embodiment of a processor included in the computing devices of FIGS. 1A and 1B;

FIG. 5 is a schematic block diagram of one embodiment of a gain module included in the processor of FIG. 4;

FIG. 6A illustrates an example of non-speech sound/noise (e.g., broad-spectrum and/or high-frequency-only information) that can be prevented by calculating and using/implementing a gain and/or gain value in the frequency domain;

FIG. 6B illustrates an example of voice-containing frequencies of human speech that can be targeted by calculating and using/implementing a gain and/or gain value in the frequency domain;

FIG. 7 is a schematic flow chart diagram illustrating one embodiment of a method for AGC with learned gains and/or calculated gains based on the frequency domain;

FIG. 8 is a schematic flow chart diagram illustrating one embodiment of a method for AGC with learned gains; and

FIG. 9 is a schematic flow chart diagram illustrating one embodiment of a method for AGC with calculated gains based on the frequency domain.

### DETAILED DESCRIPTION

As will be appreciated by one skilled in the art, aspects of the embodiments may be embodied as a system, apparatus, method, or program product. Accordingly, embodiments may take the form of an entirely hardware embodiment, an entirely software embodiment (including firmware, resident software, micro-code, etc.) or an embodiment combining software and hardware aspects that may all generally be referred to herein as a circuit, module, or system. Furthermore, embodiments may take the form of a program product embodied in one or more computer-readable storage devices storing machine readable code, computer-readable code, and/or program code, referred hereafter as code. The storage devices may be tangible, non-transitory, and/or non-transmission. The storage devices may not embody signals. In a certain embodiment, the storage devices only employ signals for accessing code.

Certain of the functional units described in this specification have been labeled as modules, in order to more particularly emphasize their implementation independence. For example, a module may be implemented as a hardware circuit comprising custom very-large-scale integration (VLSI) circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in code and/or software for execution by various types of processors. An identified module of code may, for instance, include one or more physical or logical blocks of executable code which may, for instance, be organized as an object, procedure, or function. Nevertheless, the executables of an identified module need not be physically located together and may include disparate instructions stored in different locations which, when joined logically together, include the module and achieve the stated purpose for the module.

Indeed, a module of code may be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations including over different computer-readable storage devices. Where a module or portions of a module are implemented in software, the software portions are stored on one or more computer-readable storage devices.

Any combination of one or more computer-readable media may be utilized. The computer-readable medium/media may include one or more computer-readable storage media. The computer-readable storage medium/media may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing.

More specific examples (e.g., a non-exhaustive and/or non-limiting list) of the storage device would include the following: an electrical connection having one or more wires, a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer-readable storage medium may be any tangible medium that can contain or store a program for use by or in connection with an instruction execution system, apparatus, or device.

Code for carrying out operations for embodiments may be written in any combination of one or more programming languages including an object-oriented programming language such as Python, Ruby, Java, Smalltalk, C++, or the like, and conventional procedural programming languages, such as the C programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Reference throughout this specification to one embodiment, an embodiment, or similar language means that a particular feature, structure, or characteristic described in connection with the embodiment is included in at least one embodiment. Thus, appearances of the phrases in one embodiment, in an embodiment, and similar language throughout this specification may, but do not necessarily, all refer to the same embodiment, but mean one or more but not all embodiments unless expressly specified otherwise. The terms including, comprising, having, and variations thereof mean including but not limited to, unless expressly specified otherwise. An enumerated listing of items does not imply that any or all of the items are mutually exclusive, unless expressly specified otherwise. The terms, “a,” “an,” and “the,” also refer to one or more unless expressly specified otherwise.

In addition, as used herein, the term, “set,” can mean one or more, unless expressly specified otherwise. The term, “sets,” can mean multiples of or a plurality of one or mores, ones or more, and/or ones or mores consistent with set theory, unless expressly specified otherwise.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatus, systems, and program products according to embodiments. It will be understood that each block of the schematic flowchart diagrams and/or schematic block diagrams, and combinations of blocks in the schematic flowchart diagrams and/or schematic block diagrams, can be implemented by code. The code may be provided to a processor of a general-purpose computer, special-purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and program products according to various embodiments. In this regard, each block in the schematic flowchart diagrams and/or schematic block diagrams may represent a module, segment, or portion of code, which includes one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

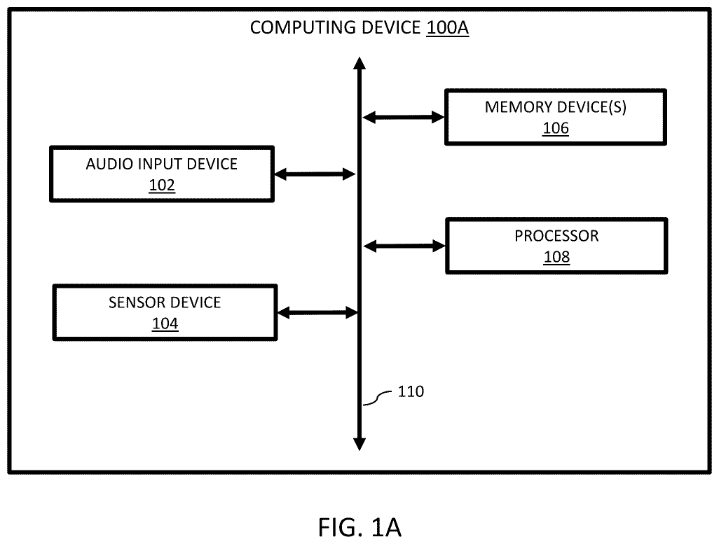

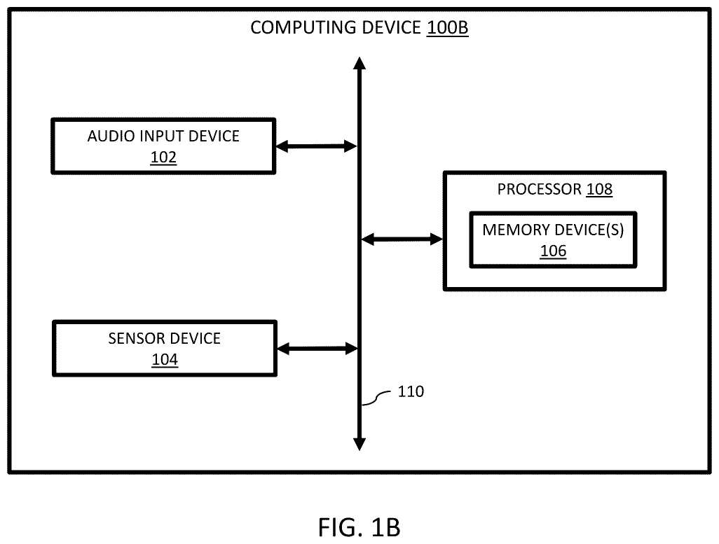

With reference to the drawings, FIG. 1A is a schematic block diagram of one embodiment of a computing device 100A (and/or computing system 100A) including Adaptive Gain Control (AGC) with learned gains and/or frequency domain gains. At least in the illustrated embodiment, the computing device 100A includes, among other components, features, and/or elements, an audio input device 102, a sensor device 104, a set of one or more memory devices 106, and a processor 108 coupled to and/or in communication with one another via a bus 110 (e.g., a wired and/or wireless bus).

A computing device 100A may include any suitable computing device and/or computing system that is known or developed in the future that can include an audio input device 102 (e.g., a microphone, etc.). Examples of a computing device 100A include, but are not limited to, a laptop computer, a desktop computer, a personal digital assistant (PDA), a video conferencing device/system, a tablet computer, a smart phone, a cellular telephone, a wearable, an Internet of Things (IoT) device, a game console, a vehicle on-board computer, a streaming device, a smart device, and a digital assistant, etc., among other similar computing devices that are possible and contemplated herein.

An audio input device 102 may include any suitable device and/or system that is/are known or developed in the future capable of sensing, capturing, and transmitting audio signals representing audio/sound, audio feeds, and/or audio streams. In various embodiments, the audio input device 102 includes at least one microphone.

A sensor device 104 may include any suitable device and/or system that is/are known or developed in the future capable of sensing, capturing, and transmitting signals representing the presence of a human/user, the distance, and/or relative distance that the human/user is away from the audio input device 102. In various embodiments, the sensor device 104 can include a motion detector, a thermal detector, and/or a camera (e.g., a camera sensor, an infrared (IR) camera, a visible imaging sensor, an RGB color camera, etc.), among other sensors, sensor devices, and/or sensing devices capable of detecting the presence of a human/user, the distance, and/or relative distance that the human/user is away from the audio input device 102 that are possible, each of which is contemplated herein.

In certain embodiments, the sensor device 104 includes and/or implements computer vision. In additional or alternative embodiments, the sensor device 104 includes and/or implements a Human Presence Detector (HPD) sensor.

A set of memory devices 106 may include any suitable quantity of memory devices 106. Further, a memory device 106 may include any suitable type of device and/or system that is known or developed in the future that can store computer-useable and/or computer-readable code. In various embodiments, a memory device 106 may include one or more non-transitory computer-usable mediums (e.g., readable, writable, etc.), which may include any non-transitory and/or persistent apparatus or device that can contain, store, communicate, propagate, and/or transport instructions, data, computer programs, software, code, routines, etc., for processing by or in connection with a computer processing device (e.g., processor 108).

A memory device 106, in some embodiments, includes volatile computer storage media. For example, a memory device 106 may include random access memory (RAM), including dynamic RAM (DRAM), synchronous dynamic RAM (SDRAM), and/or static RAM (SRAM). In other embodiments, a memory device 106 includes non-volatile computer storage media. For example, a memory device 106 may include a hard disk drive, a flash memory, and/or any other suitable non-volatile computer storage device that is known or developed in the future. In various embodiments, a memory device 106 includes both volatile and non-volatile computer storage media.

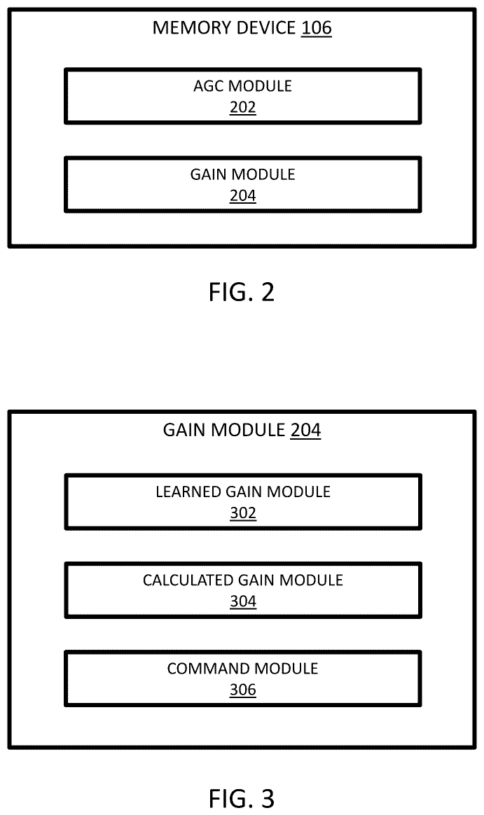

With reference now to FIG. 2, FIG. 2 is a schematic block diagram of one embodiment of a memory device 106. At least in the illustrated embodiment, the memory device 106 includes, among other components, features, and/or elements, an Adaptive Gain Control (AGC) module 202 and a gain module 204 that are configured to operate/function together when executed by the processor 108 to implement AGC with the audio input device 102 with learned gains and/or frequency domain gains.

An AGC module 202 may implement any suitable AGC algorithm, program, and/or application with the audio input device 102 that is known or developed in the future. In various embodiments, the AGC module 202 is configured to receive one or more audio signals generated by the audio input device 102 and adjust the gain of the audio signal(s).

In certain embodiments, the AGC module 202 is configured to adjust and/or modify (e.g., increase and/or decrease) the gain of the audio signals generated by the audio input device 102 to maintain a desired or target root mean square (RMS) value in the audio signal(s). The desired or target RMS may include and/or be any suitable RMS and/or RMS value(s) that is/are known or developed in the future. In some embodiments, the desired or target RMS may be represented and/or calculated utilizing the following equation:

$$\\ g = \frac{desired RMS}{\sqrt{\frac{1}{N} {\sum }_{i = 1}^{N} {x}_{i}^{2}}} ,$$

in which g is the gain (e.g., an adjustable gain, an adjustable gain value, a learned gain, a learned gain value, a calculated gain, and/or a calculated gain value, etc.), N is the number of samples in the window (e.g., the N most recent samples), and x is the microphone sample value.

In various embodiments, the AGC module 202 is configured to slowly and/or relatively slowly adjust the gain. In additional or alternative embodiments, the gain includes one or more gain values and/or a range of gains (e.g., a maximum gain and/or a minimum gain).

A gain module 204 may include any suitable hardware and/or software capable of determining when and/or what gain and/or gain value is to be applied to an AGC of an audio input device. In additional or alternative embodiments, a gain module 204 may include any suitable hardware and/or software capable of determining and/or calculating a gain for AGC of an audio input device 102.

In various embodiments, the gain module 204 is configured to transmit one or more command signals to the AGC module 202. In some embodiments, a command signal instructs the AGC module 202 when to perform its operations/functions. In additional or alternative embodiments, a command signal instructs the AGC module 202 what gain and/or gain value to apply when performing its operations/functions.

With reference to FIG. 3, FIG. 3 is a block diagram of one embodiment of a gain module 204. At least in the illustrated embodiment, a gain module 204 may include, among other components, features, and/or elements, a learned gain module 302, a calculated gain module 304, and a command module 306.

A learned gain module 302 may include any suitable hardware and/or software capable of learning a gain (e.g., g(t)) and/or gain value (e.g., g(t)). The learned gain module 302 may learn a gain and/or gain value using any suitable algorithm, technique, method, and/or process that is known or developed in the future capable of determining a gain or gain value for subsequent use and/or for future use in AGC of the input device 102 and/or the audio signal(s) generated by the input device 102.

In some embodiments, the learned gain module 302 is configured to learn a gain and/or gain value at the beginning of an audio session (e.g., a video conference, a conference call, a cellular phone call, an audio call, an audio fee, an audio stream, etc.). In certain embodiments, the learned gain module 302 is configured to monitor the user's volume (e.g., voice and/or speech) for a predetermined and/or threshold amount of time the beginning of the audio session to determine a suitable gain and/or gain value for use in an AGC corresponding to the user during the audio session, which can be any suitable amount of time capable of allowing/enabling the learned gain module 302 to determine a suitable volume for use during the audio session for the user. That is, the gain and/or gain value is learned by measuring and/or determining the volume of a user (e.g., the volume of user's voice and/or speech, etc.) for the predetermined/threshold amount of time at the beginning of the audio session and associating a gain and/or gain value that corresponds to the measured/determined volume to the audio session. In other words, the gain and/or gain value learned at the beginning of the audio session is implemented, applied, and/or used as the AGC gain of the audio input device 102 and/or the audio signal(s) generated by the audio input device 102 in an effort to maintain a consistent and/or relatively consistent volume for the user for the remainder of the audio session and/or for the entire audio session.

In certain embodiments, a learned gain and/or learned gain value determined at the beginning of an audio session is utilized in response to situations in which it may be anticipated that there will be a single user of an audio input device 102. In additional or alternative embodiments, a learned gain and/or learned gain value determined at the beginning of an audio session is utilized in response to situations in which it may be anticipated that the user is likely to remain stationary or relatively stationary during at least a portion and/or an entirety of an audio session (e.g., is unlikely or less likely to move around during the audio session). In further additional or alternative embodiments, a learned gain and/or learned gain value determined at the beginning of an audio session is utilized in response to situations in which it may be anticipated that the audio session is likely to consume a short duration of time and/or a relatively short duration of time.

The learned gain module 302, in additional or alternative embodiments, is configured to learn a gain and/or gain value during an initial audio session and/or a previous audio session. The gain and/or gain value learned during the initial/previous audio session can be implemented, applied, and/or used as the AGC gain of the audio input device 102 and/or audio signal(s) generated by the audio input device 102 for the initial/previous audio session and/or for one or more subsequent audio sessions.

The learned gain and/or learned gain value can be learned at any time during the initial/previous audio session, which can include at the beginning of an audio session (e.g., the initial/previous audio session), as discussed above. Similarly, learned gain and/or learned gain value can be applied, implemented, and/or used at any time during the subsequent/next audio session(s), which can include at the beginning, during, and/or end of the subsequent/next audio session.

In various embodiments, in implementing, applying, and/or using the learned gain and/or learned gain value as the AGC gain of the audio input device 102 and/or audio signal(s) generated by the audio input device 102 for the subsequent/next audio session(s), the learned gain module 302 is configured to determine and/or identify each subsequent/next audio session. In some embodiments, the learned gain module 302 is configured to determine/identify a subsequent/next audio session by identifying a user as the user in an initial/previous audio session. In additional or alternative embodiments, the learned gain module 302 is configured to determine/identify a subsequent/next audio session by identifying a location context (e.g., a geographic location, a GPS coordinate, a network connection (e.g., a WIFI connection, a Bluetooth® connection, an enterprise network connection, etc.), and/or an input device 102, etc.) as including one or more same location contexts of an initial/previous audio session.

In some embodiments, the learned gain module 302 is configured to disable or at least temporarily disable use of a learned gain and/or learned gain value in response to determining/detecting one or more conditions, which can include any suitable condition(s) capable of affecting the volume of a user. In certain embodiments, the learned gain module 302 is configured to disable or at least temporarily disable use of a learned gain and/or learned gain value in response to determining/detecting that one than one person/human is present in an environment surrounding the audio input device 102 (e.g., a conference room, a classroom, a meeting room, a public space (e.g., a restaurant, a coffee shop, a train station, a bus depot, an airport, a public transportation vehicle, etc.), etc.) and/or is using (e.g., speaking into) the audio input device 102 (e.g., a multi-user scenario). In other words, the various embodiments of the time-limited AGC approach discussed above can be disabled or at least temporarily disabled by the learned gain module 302.

In additional or alternative embodiments, the learned gain module 302 is configured to utilize one or more different thresholds to learn a gain and/or gain value in response to determining/detecting one or more conditions, which can include any suitable condition(s) capable of affecting the volume of a user. In certain embodiments, the learned gain module 302 is configured to learn a gain and/or gain value by allowing and/or enabling the AGC module 202 to function/operate after the audio input device 102 comes off of mute and/or the audio input device 102 is being unmuted. In embodiments in which an audio input device 102 is muted and/or effectively muted via non-transmission of the audio signals generated by the audio input device, the learned gain module 302 is configured to learn a gain and/or gain value by allowing and/or enabling the AGC module 202 to function/operate after transmission of the audio signals generated by the audio input device the audio input device 102 are resumed after a period of non-transmission of audio signals, muting, and/or effective muting of the audio input device 102.

In some embodiments, the learned gain module 302 is configured to monitor the gain and/or gain value used by the AGC module 202 for a predetermined and/or threshold amount of time after the learned gain module 302 determined/detected that the audio input device 102 is coming off of mute and/or the audio input device 102 is being unmuted, which can be any suitable amount of time capable of allowing/enabling the learned gain module 302 to determine one or more suitable gains and/or gain values used by the AGC module 202. In other words, the learned gain module 302 is configured to learn the gain and/or gain value from the AGC module 202 in situations in which the user has muted/unmuted the audio input device 102. Further, the gain and/or gain value learned by the learned gain module 302 can be implemented, applied, and/or used as the AGC gain of the audio input device 102 and/or the audio signal(s) generated by the audio input device 102 in an effort to maintain a consistent and/or relatively consistent volume for the user for the remainder of the audio session and/or for the entire audio session after the audio input device is unmuted.

In some embodiments, the learned gain module 302 is configured to learn and implement the gain and/or gain value learned from the AGC module 202 at the first or initial unmuting of the audio input device 102 for the remainder of the audio session regardless of whether the audio input device 102 is subsequently unmuted. In other embodiments, the learned gain module 302 is configured to learn and implement a new gain and/or new gain value learned from the AGC module 202 after each unmuting of the audio input device 102 for the remainder of the audio session or until a subsequent unmuting of the audio input device 102 is detected. In still other embodiments, the learned gain module 302 is configured to learn and implement a new gain and/or new gain value learned from the AGC module 202 after a preset or threshold quantity of the audio input device 102 being unmuted for the remainder of the audio session or until a subsequent preset/threshold quantity of the audio input device 102 being unmuted is detected.

The learned gain module 302, in additional or alternative embodiments, is configured to learn a minimum gain and/or minimum gain value for a user. In certain embodiments, the minimum gain and/or minimum gain value for the user is a volume at which the learned gain module 302 determines and/or detects that the user is not speaking, which can also be referred to as a nominal position and/or a learned nominal position for the user.

In some embodiments, the learned gain module 302 (or gain module 204) is configured to allow the AGC module 202 to operate/function as intended and/or as known while the user speaks to appropriately amplify and/or attenuate/dampen the volume and/or audio signal. The learned gain module 302 (or gain module 204) also simultaneously follows along with the user while the user is speaking, which can be tracked using, for example, RMS, Mel-frequency cepstral coefficients (MFCC), and/or the like. The learned gain module 302 (or gain module 204) can return to and/or implement the learned minimum gain, learned minimum gain value, nominal position, and/or learned nominal position for the user in response to determining and/or detecting that the user is no longer speaking and/or has stopped talking. In some embodiments, the gain and/or gain value decreases below the learned minimum gain, learned minimum gain value, nominal position, and/or learned nominal position for a predetermined and/or threshold period of time, which can be any suitable amount of time.

In additional or alternative embodiments, the learned gain module 302 learns the gain and/or gain value for one or more users of the audio input device 102 based on the user(s) voice. The gain and/or gain value for the user(s) of the audio input device 102 can be learned for the voice of each user using any suitable technique, technology, and/or process that is known or developed in the future.

In various embodiments, the learned gain module 302 uses voiceprint and/or a voiceprint technology to learn the gain and/or gain value. In various embodiments, the voiceprint and/or voiceprint technology can be used to learn the gain and/or gain value for at least two users (e.g., two or more users).

In certain embodiments, the voiceprint and/or voiceprint technology can be used to learn the gain and/or gain value for at least two users sharing a computing device 100A (e.g., a laptop computer) or 100B (see, e.g., FIG. 1B) during an audio session (e.g., a conference call). Additionally, or alternatively, the voiceprint and/or voiceprint technology can be used to learn the gain and/or gain value for at least two users that are located a large distance and/or relatively large distance from the computing device 100A or 100B (e.g., opposite sides of a desk or table, different locations in a room, etc.).

In further additional or alternative embodiments, the learned gain module 302 learns the gain and/or gain value for one or more users of the audio input device 102 based on the presence, location, and/or relative location of a user with respect to the computing device 100A/100B and/or audio input device 102. The gain and/or gain value for the user of the audio input device 102 can be learned based on the distance and/or relative distance that user is away from the computing device 100A/100B and/or audio input device 102, which can be determined using any suitable technique, technology, and/or process that is known or developed in the future.

Additionally or alternatively, the gain and/or gain value for a user and/or each of multiple users of an audio input device 102 can be learned based on the direction-of-arrival and/or relative direction-of-arrival of speech to the computing device 100A/100B and/or audio input device 102, which can be determined using any suitable technique, technology, and/or process that is known or developed in the future. In this manner, the learned gain module 302 can learn/detect one user, multiple users, one AGC value, and/or multiple AGC values.

In some embodiments, the learned gain module 302 learns the gain and/or gain value for a user based on the presence of a user and/or the detected distance/relative distance of the user, as determined by computer vision (e.g., the sensor device 104). In additional or alternative embodiments, the learned gain module 302 learns the gain and/or gain value for a user based on the presence of a user and/or the detected distance/relative distance of the user, as determined by a HPD sensor (e.g., the sensor device 104).

For example, if the user is in front of the computing device 100A/100B, the learned gain module 302 can learn/implement a higher minimum gain and/or gain value. In response to the user changing locations or moving (e.g., getting up), the learned gain module 302 can automatically adjust the maximum gain and/or gain value(s), which can include preemptively increasing the gain and/or gain value. In combination with one or more other embodiments discussed above, in response to the user moving and/or changing location, the AGC can be re-enabled and/or re-allowed to operate/function if it was fixed and/or set after a threshold timeout, as discussed above.

In various embodiments, the learned gain module 302 is configured to transmit one or more learned gain signals to the command module 306 in response to determining the learned gain(s) and/or learned gain value(s). The learned gain signal(s) can notify the command module 306 of the gain and/or gain value learned by the learned gain module 302 for implementation into AGC.

A calculated gain module 304 may include any suitable hardware and/or software that can calculate a gain and/or gain value for an AGC. In various embodiments, the calculated gain module 304 is configured to calculate a gain and/or gain value based on the frequency domain.

The calculated gain module 304 can calculate the gain and/or gain value based on the frequency domain using any suitable calculation, technique, algorithm, method, and/or technology that is known or developed in the future. In some embodiments, the calculated gain module 304 is configured to calculate the gain and/or gain value using weighted sum of Mel-frequency cepstral coefficients (MFCC). In certain embodiments, the calculated gain module 304 is configured to calculate the gain and/or gain value using fast Fourier transforms (FFT).

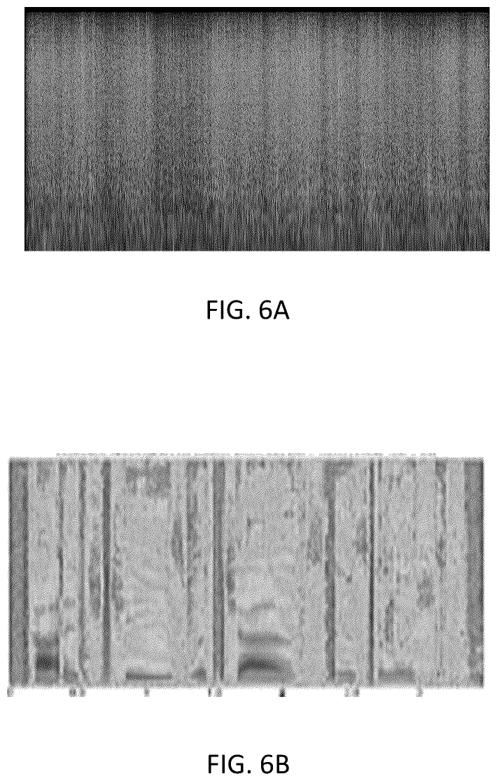

Calculating the gain and/or gain value in the frequency domain can prevent broad-spectrum and/or high-frequency-only information (e.g., background noise, rustling sounds, etc.). FIG. 6A illustrates an example of non-speech sound/noise (e.g., broad-spectrum and/or high-frequency-only information) that can be prevented by calculating and using/implementing a gain and/or gain value in the frequency domain.

In addition, calculating the gain and/or gain value in the frequency domain can enable the targeting of voice-containing frequencies. FIG. 6B illustrates an example of the voice-containing frequencies of human speech that can be targeted by calculating and using/implementing a gain and/or gain value in the frequency domain.

In view of the above, the calculated gain and/or gain value can include any suitable gain and/or gain value in the frequency domain. Further, the calculated gain and/or gain value can include any suitable gain and/or gain value in the frequency domain that can prevent broad-spectrum and/or high-frequency-only information and/or is capable of targeting the voice-containing frequencies of human speech.

In various embodiments, the calculated gain module 304 is configured to transmit one or more calculated gain signals to the command module 306 in response to determining the calculated gain(s) and/or calculated gain value(s). The calculated gain signal(s) can notify the command module 306 of the gain and/or gain value calculated by the calculated gain module 304 for implementation into AGC.

A command module 306 may include any suitable hardware and/or software that can receive learned gain signals from a learned gain module 302 and/or calculated gain signals from a calculated gain module 304. The command module 306 may further include any suitable hardware and/or software that can command the AGC module 202 when to implement/use a gain and/or gain value in the AGC and/or what gain and/or gain value to use in the AGC.

In various embodiments, the command module 306 is configured to identify when a AGC is to be allowed/enabled and/or when a learned gain, learned gain value, calculated gain, and/or calculated gain value should be implemented in the AGC. Further, the command module 306 is configured to transmit one or more command signals to the AGC module 202 to command the AGC module 202 when the AGC is to be allowed/enabled and/or when a learned gain, learned gain value, calculated gain, and/or calculated gain value should be implemented in the AGC. Moreover, the command module 306 is configured to transmit one or more command signals to the AGC module 202 to command the AGC module 202 what learned gain, learned gain value, calculated gain, and/or calculated gain value is to be implemented in the AGC.

With reference again to the AGC module 202, in various embodiments, the AGC module 202 is configured to perform the operations/functions of the AGC in response to receiving a command signal from the command module 306. Further, the AGC module 202 is configured to implement a learned gain, learned gain value, calculated gain, and/or calculated gain value in the AGC and at the time indicated in a command signal received from the command module 306.

Referring back to FIG. 1A, a processor 108 may include any suitable non-volatile/persistent hardware and/or software configured to perform and/or facilitate performing various processing functions and/or operations. In various embodiments, the processor 108 includes hardware and/or software for executing instructions in one or more modules and/or applications. The modules and/or applications executed by the processor 108 can be stored on and executed from a memory device 106 and/or from the processor 108.

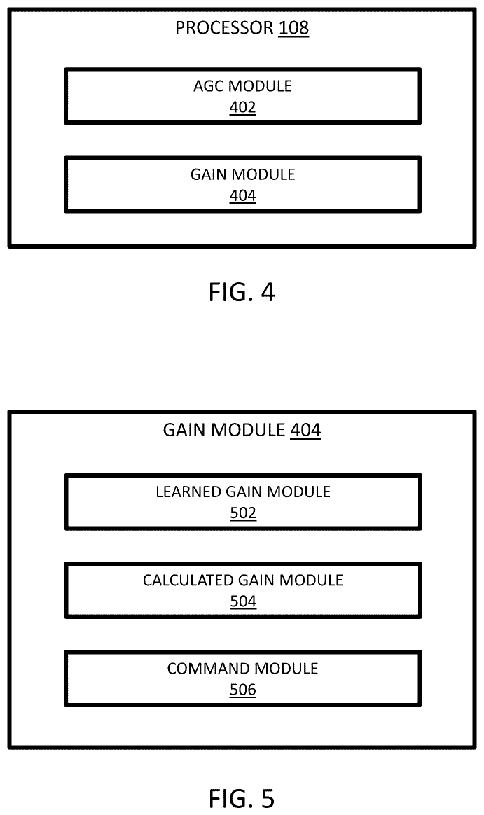

With reference to FIG. 4, FIG. 4 is a schematic block diagram of one embodiment of a processor 108. At least in the illustrated embodiment, the processor 108 includes, among other components, features, and/or elements, an AGC module 402 and a gain module 404 that are configured to operate/function together when executed by the processor 108 to implement AGC with the audio input device 102 with learned gains and/or frequency domain gains similar to the AGC module 202 and the gain module 204 in the memory device 106 discussed with reference to FIG. 2.

FIG. 5 a schematic block diagram of one embodiment of a gain module 404. At least in the illustrated embodiment, the gain module 404 includes, among other components, features, and/or elements, a learned gain module 502, a calculated gain module 504, and a command module 506 similar to the learned gain module 302, calculated gain module 304, and command module 306 in the gain module 204 discussed with reference to FIG. 3.

Referring to FIG. 1B, FIG. 1B is a block diagram of another embodiment of a computing device 100B. At least in the illustrated embodiment, the computing device 100B includes, among other components, features, and/or elements, an audio input device 102, a sensor device 104, a set of one or more memory devices 106, and a processor 108 coupled to and/or in communication with one another via a bus 110 similar to the computing device 100A discussed with reference to FIG. 1A. Alternative to the computing device 100A, the processor 108 in the computing device 100B includes the memory device(s) 106 as opposed to the memory device(s) 106 of the computing device 100B being a different device than and/or independent of the processor 108.

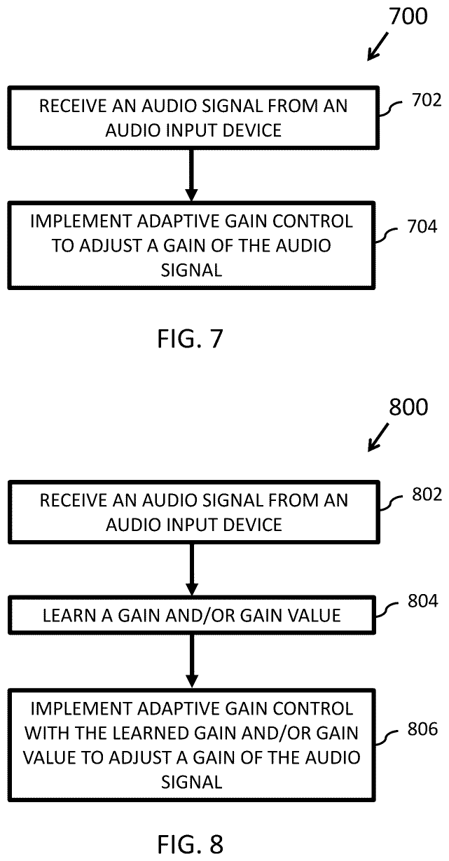

FIG. 7 is a schematic flow chart diagram illustrating one embodiment of a method 700 for Adaptive Gain Control with learned gains and/or calculated gains based on the frequency domain. At least in the illustrated embodiment, the method 700 begins by a processor (e.g., processor 108) receiving an audio signal from an audio input device 102 (block 702).

The processor 108 implements an AGC to adjust a gain of the audio signal (block 704). The gain can include a learned gain, learned gain value, a calculated gain based on the frequency domain, and/or a calculated gain value based on the frequency domain, as discussed elsewhere herein.

FIG. 8 is a schematic flow chart diagram illustrating one embodiment of a method 800 for Adaptive Gain Control with learned gains. At least in the illustrated embodiment, the method 800 begins by a processor (e.g., processor 108) receiving an audio signal from an audio input device 102 (block 802).

The processor 108 learns a gain and/or gain value (block 804) and implements an AGC with the learned gain and/or learned gain value to adjust a gain of the audio signal (block 806). The processor 108 can learn the gain and/or gain value using any embodiment or combination of embodiments for learning a gain and/or gain value, as discussed elsewhere herein.

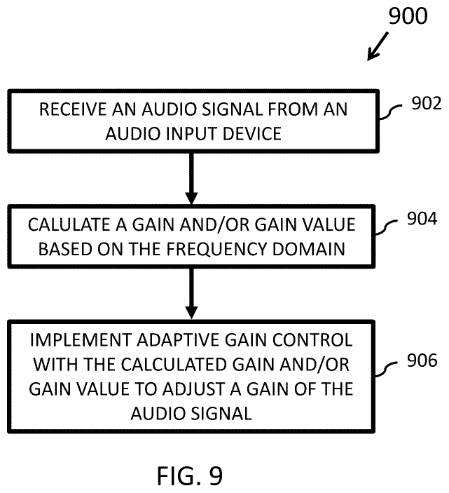

FIG. 9 is a schematic flow chart diagram illustrating one embodiment of a method 900 for Adaptive Gain Control with calculated gains based on the frequency domain. At least in the illustrated embodiment, the method 900 begins by a processor (e.g., processor 108) receiving an audio signal from an audio input device 102 (block 902).

The processor 108 calculates a gain and/or gain value based on the frequency domain (block 904) and implements an AGC with the calculated gain and/or calculated gain value to adjust a gain of the audio signal (block 906). The processor 108 can calculate the gain and/or gain value using any embodiment or combination of embodiments for calculating a gain and/or gain value (e.g., a weighted sum of Mel-frequency cepstral coefficients and fast Fourier transforms), as discussed elsewhere herein.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. An apparatus, comprising:
a processor; and
a memory configured to store code executable by the processor to:
receive an audio signal from an audio input device, and
implement an Adaptive Gain Control to adjust a gain of the audio signal,
wherein the gain comprises at least one of a learned gain and a calculated gain based on a frequency domain.

2. The apparatus of claim 1, wherein:
the gain comprises the learned gain; and
learning the learned gain comprises:
determining a gain at a beginning of an audio session, and
utilizing the gain determined at the beginning of the audio session for a remainder of the audio session.

3. The apparatus of claim 1, wherein:
the gain comprises the learned gain; and
learning the learned gain comprises:
determining the gain during an audio session, and
utilizing the gain determined during the audio session for at least one subsequent audio session.

4. The apparatus of claim 1, wherein:
the gain comprises the learned gain; and
learning the learned gain comprises:
determining a first gain for a first user,
associating a first voiceprint and the first gain,
determining a second gain for a second user,
associating a second voiceprint and the second gain,
utilizing the first gain associated with the first voiceprint in response to determining that a first current user is the first user, and
utilizing the second gain associated with the second voiceprint in response to determining that a second current user is the second user.

5. The apparatus of claim 1, wherein:
the executable code further causes the processor to:
receive a plurality of sensor signals from at least one sensor device, each sensor signal including sensor data, and
one of:
determine the learned gain based on a direction that speech from a single user is received by the audio input device, and
determine that a plurality of users are using the audio input device based on the audio input device receiving speech from a plurality of directions,
wherein the at least one sensor device comprises at least one of a microphone and a camera.

6. The apparatus of claim 1, wherein:
the gain comprises the calculated gain; and
adjusting the gain comprises applying one of a weighted sum of Mel-frequency cepstral coefficients and fast Fourier transforms to the audio signal.

7. The apparatus of claim 1, wherein:
the gain comprises the calculated gain; and
learning the learned gain comprises:
determining a first portion of the audio signal that is speech,
determining a second portion of the audio signal that is non-speech, and
calculating a gain based on the first portion of the audio signal that is speech.

8. A method, comprising:
receiving, by a processor, an audio signal from an audio input device; and
implementing an Adaptive Gain Control to adjust a gain of the audio signal,
wherein the gain comprises at least one of a learned gain and a calculated gain based on a frequency domain.

9. The method of claim 8, wherein:
the gain comprises the learned gain; and
learning the learned gain comprises:
determining a gain at a beginning of an audio session, and
utilizing the gain determined at the beginning of the audio session for a remainder of the audio session.

10. The method of claim 8, wherein:
the gain comprises the learned gain; and
learning the learned gain comprises:
determining the gain during an audio session, and
utilizing the gain determined during the audio session for at least one subsequent audio session.

11. The method of claim 8, wherein:
the gain comprises the learned gain; and
learning the learned gain comprises:
determining a first gain for a first user,
associating a first voiceprint and the first gain,
determining a second gain for a second user,
associating a second voiceprint and the second gain,
utilizing the first gain associated with the first voiceprint in response to determining that a first current user is the first user, and
utilizing the second gain associated with the second voiceprint in response to determining that a second current user is the second user.

12. The method of claim 8, further comprising:
receive a plurality of sensor signals from at least one sensor device, each sensor signal including sensor data; and
one of:
determining the learned gain based on a direction that speech from a single user is received by the audio input device, and
determining that a plurality of users are using the audio input device based on the audio input device receiving speech from a plurality of directions,
wherein the at least one sensor device comprises at least one of a microphone and a camera.

13. The method of claim 8, wherein:
the gain comprises the calculated gain; and
learning the learned gain comprises:
determining a first portion of the audio signal that is speech,
determining a second portion of the audio signal that is non-speech, and
calculating a gain based on the first portion of the audio signal that is speech.

14. The method of claim 8, wherein:
the gain comprises the calculated gain; and
adjusting the gain comprises applying one of a weighted sum of Mel-frequency cepstral coefficients and fast Fourier transforms to the audio signal.

15. A computer program product comprising a computer-readable storage device including code embodied therewith, the code executable by a processor to cause the processor to:
receive an audio signal from an audio input device; and
implement an Adaptive Gain Control to adjust a gain of the audio signal,
wherein the gain comprises at least one of a learned gain and a calculated gain based on a frequency domain.

16. The computer program product of claim 15, wherein:
the gain comprises the learned gain; and
learning the learned gain comprises:
determining a gain at a beginning of an audio session, and
utilizing the gain determined at the beginning of the audio session for at least one of:
a remainder of the audio session, and
at least one subsequent audio session.

17. The computer program product of claim 15, wherein:
the gain comprises the learned gain; and
learning the learned gain comprises:
determining a first gain for a first user,
associating a first voiceprint and the first gain,
determining a second gain for a second user,
associating a second voiceprint and the second gain,
utilizing the first gain associated with the first voiceprint in response to determining that a first current user is the first user, and
utilizing the second gain associated with the second voiceprint in response to determining that a second current user is the second user.

18. The computer program product of claim 15, wherein the executable code further causes the processor to:
receive a plurality of sensor signals from at least one sensor device, each sensor signal including sensor data; and
one of:
determine the learned gain based on a direction that speech from a single user is received by the audio input device, and
determine that a plurality of users are using the audio input device based on the audio input device receiving speech from a plurality of directions,
wherein the at least one sensor device comprises at least one of a microphone and a camera.

19. The computer program product of claim 15, wherein:
the gain comprises the calculated gain; and
learning the learned gain comprises:
determining a first portion of the audio signal that is speech,
determining a second portion of the audio signal that is non-speech, and
calculating a gain based on the first portion of the audio signal that is speech.

20. The computer program product of claim 15, wherein:
the gain comprises the calculated gain; and
adjusting the gain comprises applying one of a weighted sum of Mel-frequency cepstral coefficients and fast Fourier transforms to the audio signal.
